(19) United States
(12) Patent Application Publication
(10) Pub. No.: US 2012/0154569 A1
(43) Pub. Date: Jun. 21, 2012

(54) Waterproof Housing And Control Arm

(75) Inventor: Terry J. Geddes, Cairns (AU)

(73) Assignee: Indepth Pth Ltd, Queensland (AU)

(21) Appl. No.: 13/393,015

(22) PCT Filed: Aug. 19, 2010
(86) PCT No.: PCT/AU10/01064

§ 371 Date: Feb. 28, 2012

(30) Foreign Application Priority Data
Aug. 28, 2009 (AU) 2009904108

(51) Int. Cl. H05K 5/02; H04N 5/225

(52) U.S. Cl. 348/81; 312/223.1; 312/223.4; 348/E05.026

(57) ABSTRACT

A waterproof housing (10) enables convenient underwater operation of a touch-screen interface of an electronic device. The housing (10) includes a casing (12) that defines a cavity (30) in which the electronic device can be mounted, the casing (12) including a window (26) through which the touch-screen interface can be viewed. A swivel mechanism (14) is mounted within a hole in the casing, wherein the swivel mechanism (14) is rotatable in three degrees of freedom. A control arm (16) slidingly engages and extends through the swivel mechanism (14), wherein a manipulating part (34) of the control arm (16) projects into the cavity (30) and a handle part (36) of the control arm (16) is disposed outside the casing (12). In use, the handle part (36) of the control arm (16) may be operated to move the manipulating part (34) of the control arm (16) in three dimensions to operate the touch-screen interface of the electronic device.

### FIELD OF THE INVENTION

The present invention relates to a waterproof housing and a universal control arm or joystick. In particular, although not exclusively, the invention relates to a waterproof housing for electronic equipment having a touch-screen interface operable via a universal control arm or joystick.

### BACKGROUND TO THE INVENTION

In order to operate a non-waterproof camera under water, the camera must be placed in some type of waterproof housing or pouch. Pouches can be convenient as they may be universally used for a large number of different cameras, and the operating buttons and/or a touch screen may be actuated through the pouch. However, pouches have limitations on the depth they can be operated at before starting to leak. More robust waterproof housings are generally custom designed for a particular camera form factor, and include push buttons and/or dials that correspond with push buttons and/or dials of the specific camera form factor. The camera then can be operated by actuating the buttons and/or dials of the waterproof housing.

Digital cameras (including digital video cameras) increasingly have touch-screen interfaces. As such touch-screen interfaces are generally widely variable and dynamic, a push button solution that operates over only a limited area of a touch-screen within a waterproof housing is not preferred. Thus according to the prior art it is generally very difficult for a touch screen to be effectively controlled by a mechanism of a robust waterproof housing.

### OBJECT OF THE INVENTION

It is an object of the present invention to overcome or alleviate one or more limitations of the prior art, including providing an improved waterproof housing.

### SUMMARY OF THE INVENTION

According to one aspect, the present invention is a waterproof housing comprising:

a casing that defines a cavity in which an electronic device having a touch-screen interface can be mounted, the casing including a window through which the touch-screen interface can be viewed;

a swivel mechanism mounted within a hole in the casing, wherein the swivel mechanism is rotatable in three degrees of freedom; and

a control arm slidingly engaging and extending through the swivel mechanism, wherein a manipulating part of the control arm projects into the cavity and a handle part of the control arm is disposed outside the casing so that, in use, the handle part of the control arm may be operated to move the manipulating part of the control arm in three dimensions to operate the touch-screen interface of the electronic device.

Preferably, the swivel mechanism comprises:
a socket fixed in the hole in the casing; and
a ball element held within the socket in a sliding engagement to enable the ball element to rotate within the socket in three degrees of freedom, the ball element having a passage therethrough in which the control arm is receivable.

Preferably, the swivel mechanism includes at least one o-ring which seats between the socket and the ball element.

Preferably, the swivel mechanism includes at least one o-ring in the passage of the ball element and the control arm extends through the o-ring.

Preferably, the waterproof housing includes buttons that are depressible from the outside of the waterproof casing to operate buttons of the electronic device mounted in the cavity.

Preferably, the casing comprises a rigid sleeve and transparent windows that seal opposite ends of the rigid sleeve, wherein the swivel mechanism is fixed in a wall of the sleeve.

Preferably, the control arm comprises a curved end section having a rubberised tip.

Preferably, the waterproof housing includes at least one handle fixed thereto.

Preferably, the electronic device is a video camera or smart phone.

### BRIEF DESCRIPTION OF THE DRAWINGS

To assist in understanding the invention and to enable a person skilled in the art to put the invention into practical effect, preferred embodiments of the invention are described below by way of example only with reference to the accompanying drawings, in which:

FIG. 1 is a front perspective view of one embodiment of a waterproof housing in accordance with the invention;

FIG. 2 is a rear perspective view of the waterproof housing of FIG. 1, including a digital video camera mounted in the waterproof housing;

FIG. 3 is a cross sectional view of the control arm and swivel mechanism of the waterproof housing of FIG. 1;

FIG. 4 is a top view of the control arm and swivel mechanism of the waterproof housing of FIG. 1; and

FIG. 5 is a sectional view of another embodiment of a waterproof housing in accordance with the invention.

Those skilled in the art will appreciate that minor deviations from the symmetrical layout of components as illustrated in the drawings will not detract from the proper functioning of the disclosed embodiments of the present invention.

### DETAILED DESCRIPTION OF THE INVENTION

One embodiment of the present invention comprises a waterproof housing including a casing, a swivel mechanism and a control arm. Elements of the invention are illustrated in concise outline form in the drawings, showing only those specific details that are necessary to understanding the embodiments of the present invention, but so as not to clutter the disclosure with excessive detail that will be obvious to those of ordinary skill in the art in light of the present description.

In this patent specification, adjectives such as first and second, left and right, front and rear, top and bottom, etc., are used solely to define one element or method step from another element or method step without necessarily requiring a specific relative position or sequence that is described by the adjectives. Words such as “comprises” or “includes” are not used to define an exclusive set of elements or method steps. Rather, such words merely define a minimum set of elements or method steps included in a particular embodiment of the present invention.

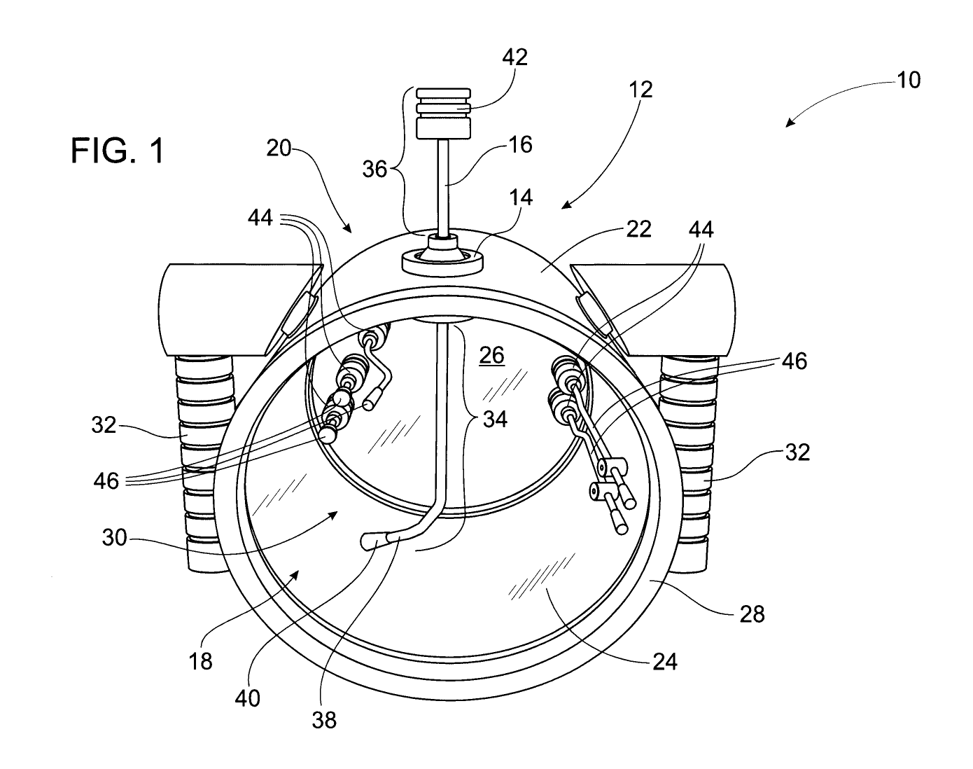

Referring to FIG. 1, one embodiment of a waterproof housing 10 comprises a casing 12, a swivel mechanism 14 and a control arm 16. The housing 10 has a front end 18 and a rear end 20.

The casing 12 comprises a sleeve 22, a front plate 24 that seals the front end 18 of the sleeve 22, and a transparent rear window 26 that seals the rear end 20 of the sleeve 22. The casing 12 defines a cavity 30. The front plate 24, which also may be transparent, is releasably fixed to the sleeve 22 by a collar 28 that threads onto the front end 18 of the sleeve 22 to clamp the plate 24 between the sleeve 22 and the collar 28. The rear window 26 is fixed in a bore of the sleeve 22. Two L-shaped handles 32 are fixed opposite each other along the circumference of the sleeve 22. The handles 32 allow an operator of the housing 10 to securely grip the housing 10 during underwater operation.

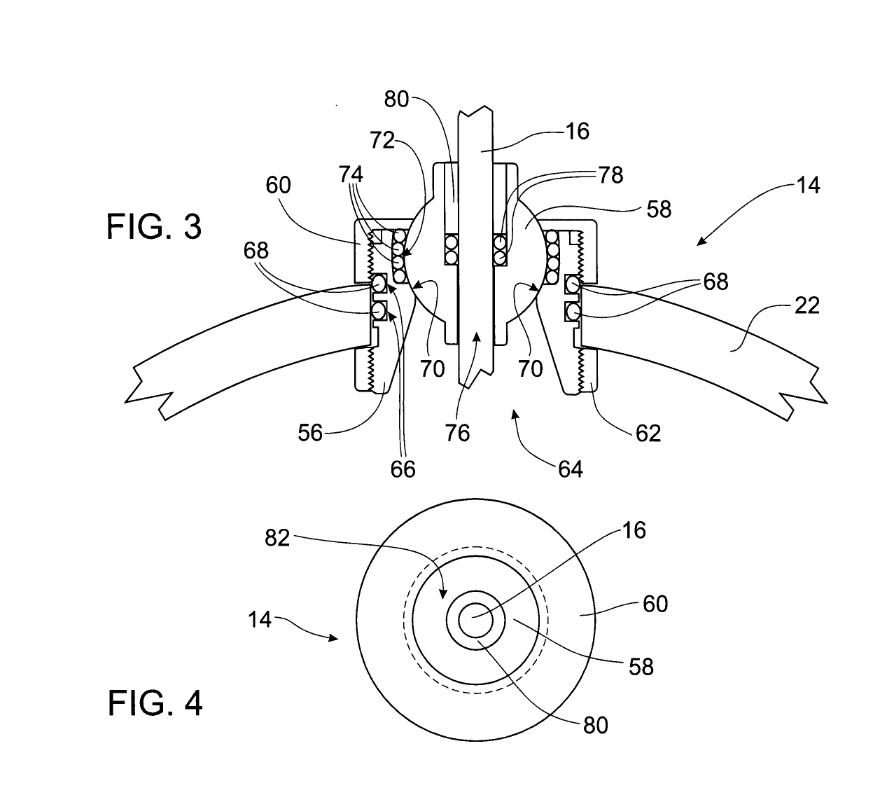

The swivel mechanism 14 is fixed within a hole in the sleeve 22. The swivel mechanism 14 is discussed in more detail below with reference to FIGS. 3 and 4.

The control arm 16 slidingly engages and extends through the swivel mechanism 14. The control arm 16 is supported by the swivel mechanism 14, from which it is suspended. The control arm 16 comprises a manipulating part 34 within the cavity 30 and a handle part 36 outside the sleeve 22. The manipulating part 34 has a curved end section 38 with a rubberised tip 40. The handle part 36 has a knob 42 at its distal end.

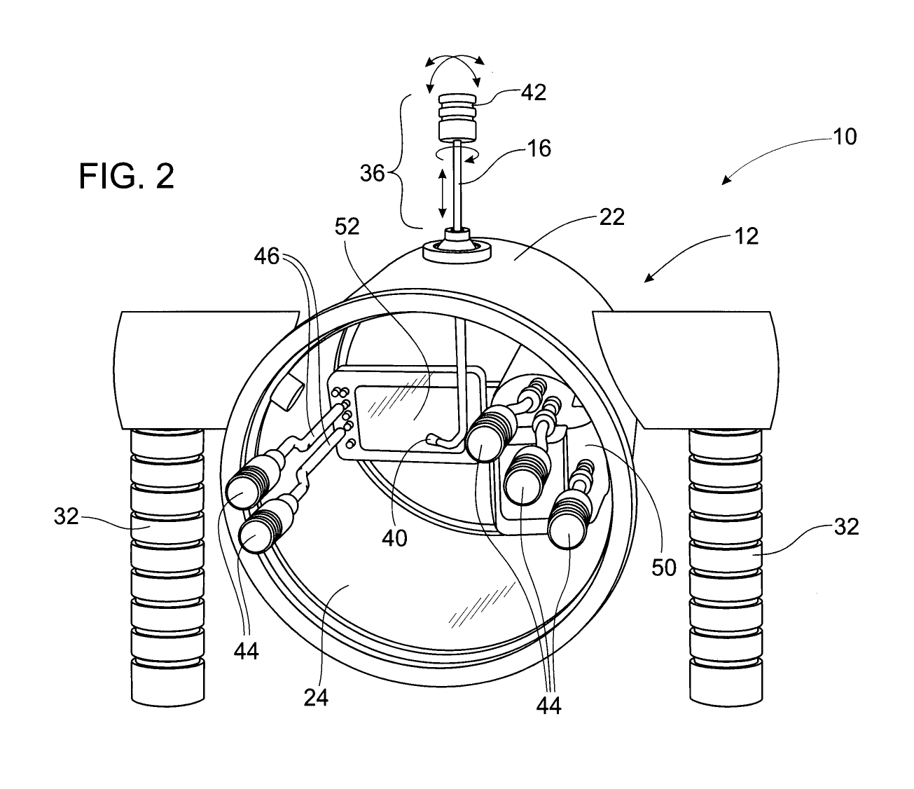

The housing 10 includes push buttons 44 attached to the rear window 26. The push buttons 44 have actuators 46 that project into the cavity 30. The buttons 44 and actuators 46 are arranged to correspond with operating buttons of an electronic device such as a digital video camera, as is described in more detail with reference to FIG. 2.

Referring to FIG. 2, a digital video camera 50 is mounted within the cavity 30 of the casing 12 so that a lens of the camera 50 faces a transparent section of the front plate 24. The video camera 50 is mounted by means of a mounting shoe which threads into a tripod screw hole at an underside of the video camera 50. The video camera 50 has a flip open touch screen 52. As such, control objects for operation of the video camera 50 are displayed on the touch screen 52 and selected by touching the screen 52 at the location of the control object. Various other electronic devices, such as smart phones, recorders, or other underwater data collection devices also can be mounted in the casing 12.

The present invention provides for the screen 52 to be touched by the rubberised tip 40 of the control arm 16. The control arm 16 can be swivelled by operating the handle part 36 thereof. A user grips the knob 42 to swivel the control arm 16 longitudinally and transversely, to translate the control arm 16 up and down, and to rotate the control arm 16 relative to the touch screen 52. The tip 40 thus may be easily and naturally moved in three dimensions to touch any location on the touch screen 52, and thereby enables full control of the video camera 50 via the touch screen 52.

FIG. 3, shows a cross-sectional view of the swivel mechanism 14. The swivel mechanism 14 comprises a socket 56, a ball element 58, an outer lock ring 60, and an inner lock ring 62.

The socket 56 is fixed in a hole 64 in the sleeve 22. The socket 56 has screw threads at opposite ends, which are engaged by the outer lock ring 60 and the inner lock ring 62, respectively. The outer lock ring 60 threads onto the socket 56 from one end to abut the outside of the sleeve 22, and the inner lock ring 62 threads onto the socket 56 from the other end to abut the inside of the sleeve 22, thereby to fix the socket 56 in the hole 64 in the sleeve 22. The socket 56 has two surrounding annular grooves 66 in which o-rings 68 are received. The o-rings 68 seal the interface between the socket 56 and the sleeve 22. The socket 56 further has an internal contact face 70 against which the ball element 58 seats. An annular channel 72 is defined adjacent the contact face 70, and four polymer o-rings 74 are received in the annular channel 72 in a stacked arrangement. The channel 72 has a concave wall that allows the stack of o-rings 74 to conform to the shape of the ball element 58. The uppermost o-ring 74 in the stack of o-rings 74 abuts the outer lock ring 60, and the lowermost o-ring 74 in the stack of o-rings 74 abuts a shoulder at the side of the annular channel 72. The ball element 58 is thus operable to be swivelled and rotated relative to the socket 56 in three degrees of freedom (i.e., roll, pitch, and yaw). The o-rings 74 seal the interface between the socket 56 and the ball element 58, preventing ingress of water into the casing 12.

The ball element 58 has a central passage 76 in which the shaft of the control arm 16 is slidingly engaged. The control arm 16 is thus moveable and can slide up and down in the passage 76. A section of the passage 76 has a wider bore, in which two o-rings 78 are located. The o-rings 78 seal the interface between the control arm 16 and the ball element 58, preventing ingress of water into the casing 12 via the passage 76. The o-rings 78 are captured in the passage 76 by a lock sleeve 80 which threads into the passage 76 to capture the o-rings 78 between the lock sleeve 80 and a shoulder where the passage 76 narrows. Further, the o-rings 78 grip the shaft of the control arm 16, thereby to suspend the control arm 16 in the passage 76.

The o-rings 74, 78 are self-lubricating during use of the control arm 16. Rotation of the ball element 58 causes lubricant on the surface of the ball element 58 to re-coat the o-rings 74. Similarly, rotation or translation of the control arm 16 in the passage 76 causes lubricant on the surface of the control arm 16 to re-coat the o-rings 78.

FIG. 4 shows a top view of the swivel mechanism 14. The outer lock ring 60 includes an opening 82 having a diameter slightly smaller than the diameter of the ball element 58, thereby securing the ball element 58 in the swivel mechanism 14. The diameter of the opening 82 is large enough to allow the ball element 58 to swivel relative to the outer lock ring 60.

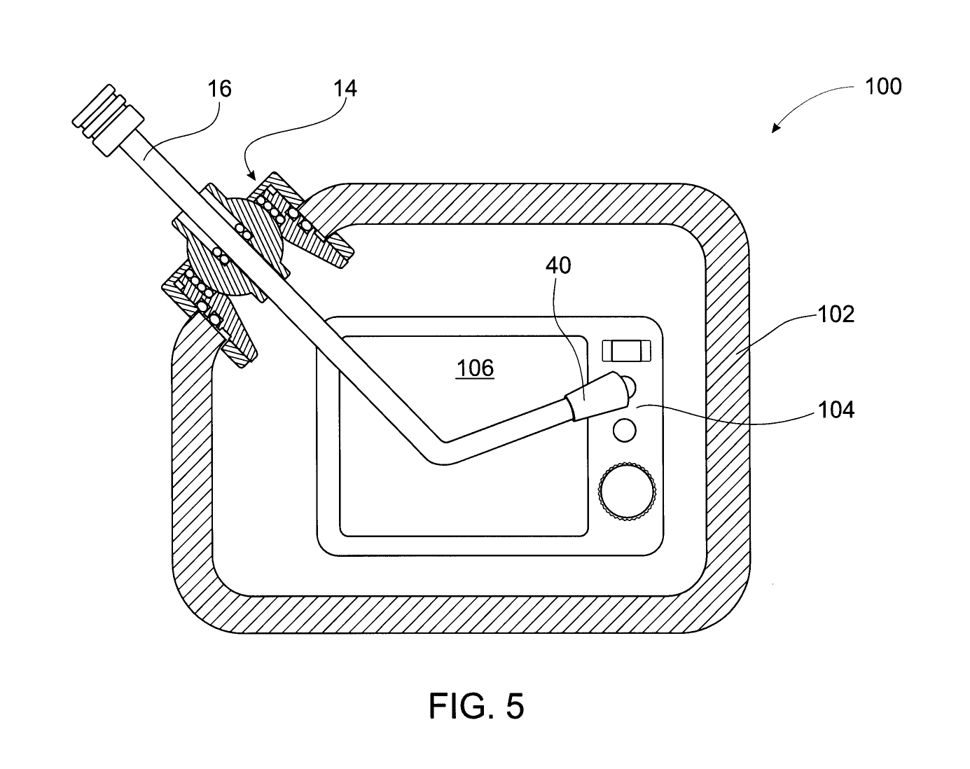

FIG. 5 shows an alternative embodiment of a waterproof housing 100 in accordance with the invention. The housing 100 has a casing 102 which is designed and configured to receive a digital camera 104 of a traditional form factor. The casing 102 is substantially rectangular in cross-section. The swivel mechanism 14 of the housing 100 is identical to the swivel mechanism 14 of the housing 10. However, according to this embodiment the swivel mechanism 14 is located at a corner of the casing 102. The digital camera 104 has a touch screen 106 which is operated by being touched by the tip 40 of the control arm 16.

As will be understood by those having ordinary skill in the art, the housings 10, 100 and the swivel mechanism 14 can be fabricated from any suitable corrosion resistant materials, including stainless steel, various coated alloys, and high strength polymers. The front plate 24 and rear window 26 may be made of various transparent and non-transparent materials such as glass, transparent polymers, hard plastics and metals.

In summary, advantages of some embodiments of the present invention include having a waterproof housing 10, 100 including a control arm 16 to operate a touch-screen 52, 106 of a camera 50, 104 within the housing 10, 100. The control arm 16 is moveable in three dimensions to allow the tip 40 of the control arm 16 to touch any point on the touch-screen 52, 106. The waterproof housing 10, 100 thus provides for improved operation of the camera 50, 104 within the housing 10, 100, and enables various camera designs to be fitted and operated inside a single housing design.

The above description of various embodiments of the present invention is provided for purposes of description to one of ordinary skill in the related art. It is not intended to be exhaustive or to limit the invention to a single disclosed embodiment. As mentioned above, numerous alternatives and variations to the present invention will be apparent to those skilled in the art of the above teaching. Accordingly, while some alternative embodiments have been discussed specifically, other embodiments will be apparent or relatively easily developed by those of ordinary skill in the art. Accordingly, this patent specification is intended to embrace all alternatives, modifications and variations of the present invention that have been discussed herein, and other embodiments that fall within the spirit and scope of the above described invention.

1. A waterproof housing comprising:
a casing that defines a cavity in which an electronic device having a touch-screen interface can be mounted, the casing including a window through which the touch-screen interface can be viewed;
a swivel mechanism mounted within a hole in the casing, wherein the swivel mechanism is rotatable in three degrees of freedom; and
a control arm slidingly engaging and extending through the swivel mechanism, wherein a manipulating part of the control arm projects into the cavity and a handle part of the control arm is disposed outside the casing so that, in use, the handle part of the control arm may be operated to move the manipulating part of the control arm in three dimensions to operate the touch-screen interface of the electronic device.

2. The waterproof housing of claim 1, wherein the swivel mechanism comprises:
a socket fixed in the hole in the casing; and
a ball element held within the socket in a sliding engagement to enable the ball element to rotate within the socket in three degrees of freedom, the ball element having a passage there-through in which the control arm is receivable.

3. The waterproof housing of claim 2, wherein the swivel mechanism includes at least one o-ring which seats between the socket and the ball element.

4. The waterproof housing of claim 2, wherein the swivel mechanism includes at least one o-ring in the passage of the ball element and the control arm extends through the o-ring.

5. The waterproof housing of claim 1, wherein the waterproof housing includes buttons that are depressible from the outside of the waterproof casing to operate buttons of the electronic device mounted in the cavity.

6. The waterproof housing of claim 1, wherein the casing comprises a rigid sleeve and transparent windows that seal opposite ends of the rigid sleeve, wherein the swivel mechanism is fixed in a wall of the sleeve.

7. The waterproof housing of claim 1, wherein the control arm comprises a curved end section having a rubberised tip.

8. The waterproof housing of claim 1, wherein the waterproof housing includes at least one handle fixed thereto.

9. The waterproof housing of claim 1, wherein the electronic device is a video camera or smart phone.
